(19) United States
(12) Patent Application Publication
(10) Pub. No.: US 2020/0091094 A1
(43) Pub. Date: Mar. 19, 2020

(54) INTEGRATED FILTER TECHNOLOGY WITH EMBEDDED DEVICES

(71) Applicant: QUALCOMM Incorporated, San Diego, CA (US)

(72) Inventors: Changhan Hobie YUN, San Diego, CA (US); Mario Francisco VELEZ, San Diego, CA (US); Nosun PARK, Incheon (KR); Niranjan Sunil MUDAKATTE, San Diego, CA (US); Wei-Chuan CHEN, San Diego, CA (US); Paragkumar Ajaybhai THADESAR, San Diego, CA (US); Christopher POLLOCK, San Diego, CA (US); Xiaoju YU, San Diego, CA (US); Rongguo ZHOU, San Diego, CA (US); Kai LIU, San Diego, CA (US); Jonghae KIM, San Diego, CA (US)

(21) Appl. No.: 16/132,323

(22) Filed: Sep. 14, 2018

(51) Int. Cl. H01L 23/64; H01L 23/31; H01L 23/15; H03H 9/54; H03H 9/64; H03H 7/01; H03H 3/02; H03H 3/08

(52) U.S. Cl. CPC H01L 23/645; H01L 23/642; H01L 23/3135; H01L 23/15; H03H 3/08; H03H 9/64; H03H 7/0115; H03H 3/02; H03H 9/542

(57) ABSTRACT

A filter including an insulating die having a plurality of MIM (Metal Insulator Metal) capacitors disposed within the die is disclosed. A 2.5D (2.5 Dimensional) inductor disposed within a redistribution layer (RDL) is electrically coupled to at least one of the plurality of MIM capacitors in the die. A 3D (3 Dimensional) inductor is disposed around the die and is electrically coupled to at least one of the plurality of MIM capacitors.

### FIELD OF DISCLOSURE

The present disclosure is related to electronic devices having integrated inductors and in further aspects to filters using integrated inductors.

### BACKGROUND

Integrated circuit technology has achieved great strides in advancing computing power through miniaturization of active components. Integrative passive components have also been miniaturized. As frequencies and data rates get higher, there is a need for further miniaturization of integrated passive components, for example, filters which include inductive elements, which are some of the largest elements in an integrated circuit device. Additionally, to improve quality of received signals, certain components of a mobile device may be formed on an insulating substrate (e.g., glass substrate). For example, a circuit component may be formed on a glass substrate to “isolate” the component in order to reduce effects of noise from other components of the mobile device.

In some applications, a size of the glass substrate may limit a number or size of components that may be formed on the glass substrate. Additionally, as inductors are used for filters at different and higher frequencies (e.g., into the GHz and millimeter wave frequencies), the quality factor (or Q) of the passive components (e.g., inductor, capacitor) must be maintained or improved, even while a reduction in the overall size is desired.

FIG. 1 illustrates one example, from US Patent Publication No. 2018/0026666, assigned to the assignee of the present application, of a glass substrate 102 filled to form through-glass vias (TGVs) of a 3D inductor 104. TGVs of the 3D inductor 104 may be connected using traces to form the 3D inductor. FIG. 1 also illustrates that the 3D inductor 104 may have a wrap-around configuration that wraps around the semiconductor die 106. To illustrate, the traces may be disposed above a first surface (e.g., a top surface) of the semiconductor die 106, and the traces may be disposed below a second surface (e.g., a bottom surface) of the semiconductor die 106. The TGVs may be disposed on opposite sides of the semiconductor die 106. A second 3D inductor 108 may also be formed in a similar manner

### SUMMARY

The following summary identifies some features and is not intended to be an exclusive or exhaustive description of the disclosed subject matter. Additional features and further details are found in the detailed description and appended claims. Inclusion in the Summary is not reflective of importance. Additional aspects will become apparent to persons skilled in the art upon reading the following detailed description and viewing the drawings that form a part thereof.

One aspect disclosed includes a filter comprising a die having a plurality of

Metal Insulator Metal (MIM) capacitors disposed within the die. The filter also includes a 2.5D (2.5 Dimensional) inductor disposed within a redistribution layer (RDL) and electrically coupled to at least one of the plurality of MIM capacitors. The filter further includes a 3D (3 Dimensional) inductor, wherein the 3D inductor is disposed around the die and is electrically coupled to at least one of the plurality of MIM capacitors.

Additional aspects include a method for fabricating a filter comprising fabricating a die having a plurality of Metal Insulator Metal (MIM) capacitors disposed within the die. The method also includes forming a 2.5D inductor disposed within a redistribution layer (RDL) and electrically coupling the 2.5D inductor to at least one of the plurality of MIM capacitors. The method further includes forming a 3D inductor around the die and electrically coupling the 3D inductor to at least one of the plurality of MIM capacitors.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of embodiments of the present disclosure and are provided solely for illustration of the various aspects disclosed and not limitation thereof.

FIG. 1 is a graphical illustration of a 3D inductor disclosed in the related art.

FIG. 2 is a schematic illustration of a filter according to one aspect of the disclosure.

FIG. 3 is a graphical illustration of a filter according to an aspect of the disclosure.

FIG. 4 is a graphical illustration of an alternate view of the filter illustrated in FIG. 3.

FIG. 5 is a magnified illustration of a portion of the filter in FIG. 3.

FIG. 6 is a graphical illustration of an alternative filter configuration.

FIG. 7 shows one example functional schematic of devices that can include one or more filters in accordance with some examples of the disclosure.

FIG. 8 is a graphical illustration of part of a process that may be used to form filters according to aspects of the disclosure.

FIG. 9 is a graphical illustration of part of the process that may be used to form filters according to aspects of the disclosure.

FIG. 10 is a graphical illustration of part of the process that may be used to form filters according to aspects of the disclosure.

FIG. 11 is a graphical illustration of part of the process that may be used to form filters according to aspects of the disclosure.

FIG. 12 is a graphical illustration of part of the process that may be used to form filters according to aspects of the disclosure.

FIG. 13 is a graphical illustration depicting aspects of an alternate or optional filter configuration according to aspects of the disclosure.

FIG. 14 is a graphical illustration depicting aspects of an alternate or optional filter configuration according to aspects of the disclosure.

FIG. 15 is a graphical illustration depicting aspects of an alternate or optional filter configuration according to aspects of the disclosure.

FIG. 16 is a graphical illustration depicting aspects of an alternate or optional filter configuration according to aspects of the disclosure.

FIG. 17 is a graphical illustration depicting aspects of an alternate or optional filter configuration according to aspects of the disclosure.

FIG. 18 is a flowchart for fabricating filter configurations according to aspects of the disclosure.

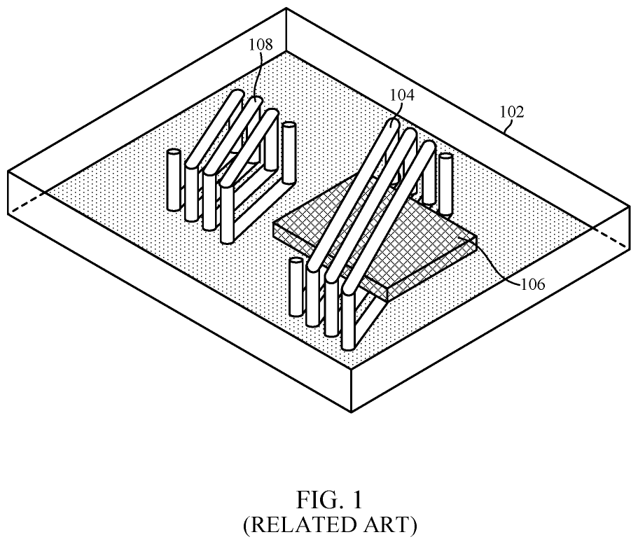

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

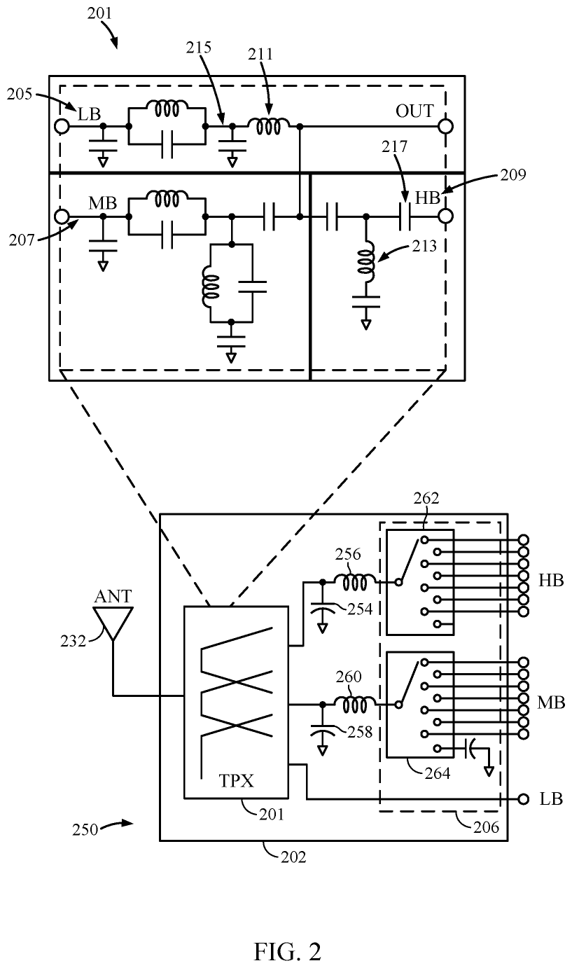

FIG. 2 is a schematic illustration of a lumped element filter, in this case a triplexer, according to one aspect of the disclosure. In FIG. 2 a triplexer 201 has various inductors, e.g. 211 and 213, and various capacitors, e.g. 215 and 217, and is arranged to comprise a triplexer. The triplexer, in this case, can couple signals from 3 separate bands to a common node, via a high-band circuit 209, a middle-band circuit 207, and a low-band circuit 205. As can be seen in FIG. 2, the triplexer is largely composed of passive components (e.g., inductors and capacitors) arranged on a substrate (e.g., a glass substrate).

FIG. 2 further illustrates an example application of the triplexer (TPX) 201. For example, the TPX 201 may be formed as a passive-on-glass (POG) device. The triplexer 201 may be integrated within a glass substrate 202. The glass substrate 202 may also include a semiconductor die 206 (e.g., a silicon semiconductor die). The semiconductor die 206 is integrated within the glass substrate 202. The semiconductor die 206 may include one or more active components, such as one or more transistors. In an illustrative example, the semiconductor die 206 includes multiple switches each including a transistor. The semiconductor die 206 is coupled to the TPX 201.

FIG. 2 also depicts an illustrative example of a circuit diagram of a device 250 that includes the glass substrate 202. The device 250 further includes an antenna 232 coupled to the triplexer 201. For example, the antenna 232 may be coupled to an input of the TPX 201. In the example of the device 250, TPX 201 includes a multiband bandpass filter. The multiband bandpass filter may include multiple bandpass filter circuits in accordance with a carrier aggregation technique. For example, the TPX 201 may include multiple bandpass filter circuits, such as a low-band filter circuit, a high-band filter circuit, and a middle-band filter circuit, as discussed above.

In addition to the TPX 201, the POG device 250 may include one or more other components, such as one or more inductors, one or more capacitors, one or more other components, or a combination thereof. For example, the TPX 201 may be coupled to a capacitor 254 and to an inductor 256. Further, the TPX 201 may be coupled to a capacitor 258 and to an inductor 260.

The semiconductor die 206 may include a plurality of switches. For example, the plurality of switches may include metal-oxide-semiconductor field-effect transistors (MOSFETs) formed within the semiconductor die 206. The plurality of switches may include a first set of one or more switches 262 coupled to the high-band circuit of the TXP 201 and may further include a second set of one or more switches 264 coupled to the middle-band circuit of the TXP 201. The semiconductor die 206 may include one or more output terminals of an input/output (1/0) interface of the semiconductor die 206.

In one aspect, the TXP 201 is configured to generate multiple signals based on the signal from the antenna 232. In an illustrative example, the TXP 201 is configured to pass a high-band (HB) signal to a first output, a middle-band (MB) signal to a second output and a low-band (LB) signal to a third output. The HB signal, the MB signal, and the LB signal may correspond to a signal sent by a transmitter in a wireless communication system. In the illustrative example of FIG. 2, the third output (LB) is not connected to a switch. In other implementations, the third output may be coupled to one or more switches of the semiconductor die 206. The semiconductor die 206 may provide one or more selected signals to another device. For example, the semiconductor die 206 may provide one or more of the HB signal, the MB signal, and the LB signal to a particular device component, such as to a low noise amplifier (LNA) of a receiver device, as an example.

The arrangement of the passive and active components in FIG. 2 is for illustrative purposes only. There are any numbers of arrangements of passive components that can be used to form such a device. Additionally, as higher frequencies are used for wireless systems, secondary effects, such as stray capacitance, stray inductance, and the skin effect may complicate filter design. Smaller and more compact filter designs may help mitigate such secondary effects.

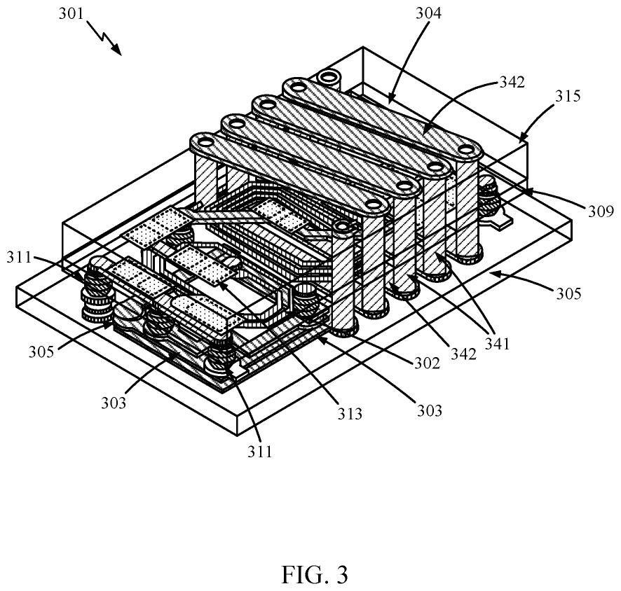

FIG. 3 is a graphical illustration of a filter 301 (illustrated as a triplexer) including 2D (2 Dimensional), 2.5D (2.5 Dimensional) and 3D (3 Dimensional) inductive portions as well as capacitive portions, according to an aspect disclosed herein. 2D inductors are shown generally at 302. An inductor, as used herein, is 2D if the inductance winding (e.g., 302) is essentially in a single plane or layer. The inductance winding illustrated is formed from conductive traces which form a conductive coil in 2 dimensions. The inductor windings (e.g., 302) may be deposited in plane, substrate, or die. In example aspects, the substrate or die may be formed of glass, high resistivity silicon, ceramic materials, organic materials or other materials with sufficient insulating properties. A 2.5D inductor (e.g., 303), as used herein, may be formed from a first conductive coil that is parallel to a second conductive coil located on separate layers in a substrate or die in a stacked configuration. For example, the 2.5D inductor (e.g., 303) may be formed using two or more layers of a redistribution layer (RDL) in substrate 305, which may be formed of glass, high resistivity silicon, ceramic materials, organic materials or other materials with sufficient insulating properties. Further, as used herein, a 3D inductor (e.g., 304) can be fabricated using vertical conductive pillars 341 substantially perpendicular to a surface of the die 309. The conductive pillars may be formed from copper or any other conductive material. Each conductive pillar 341 can be coupled to at least one other conductive pillar 341 via conductive connections 342 substantially parallel to the surface of the die 309, thereby forming a 3-dimensional inductor. In some aspects, the 3D inductor 304 may be formed by drilling holes in a substrate of die (not shown in order to more clearly illustrate the winding structure) and filling them with copper pillars or through substrate vias (TSVs), e.g., through-silicon vias, through glass vias, etc. and then using them to connect the horizontal conductive connections or traces, thereby forming a 3-dimensional inductor. Throughout this disclosure various methods of forming electrical interconnections (e.g., pillars, TSVs, etc.). The electrical interconnections may be formed, for example, by drilling holes which are then filled with conductive material. Alternatively or in addition, the electrical interconnections may be deposited in layers or formed using any conventional method known in the art. Many terms have been used in the art to describe such structures. For the purpose of this disclosure, such structures will be referred to as pillars and/or TSVs no matter how they were formed.

The illustrated filter 301 of FIG. 3 includes a high-band portion. The high-band portion may include a 2.5D inductor 303. In the present illustration, the 2.5D inductor 303 is shown having three co-planar layers (solely for illustration and not limitation), specifically, three parallel inductor coils formed from three layers of RDL in substrate 305. The RDL of substrate 305 is attached to a die 309 via solder balls 311. In one aspect this is accomplished using a flip chip process. Disposed within the die 309 is a 2D inductor 302 that can be used for the middle-band frequencies in the present illustrative example. The die 309 may also contain Metal Insulator Metal (MIM) capacitors 313 made from metal layers separated by the insulating layers in die 309. The die 309 may be formed of glass, high resistivity silicon, or other insulating materials may be used. Additionally, the die 309 may be mounted on a glass substrate 315. A compact low pass filter can be formed by the 3D inductor 304 being wrapped in whole or in part around the die 309, as illustrated in FIG. 3.

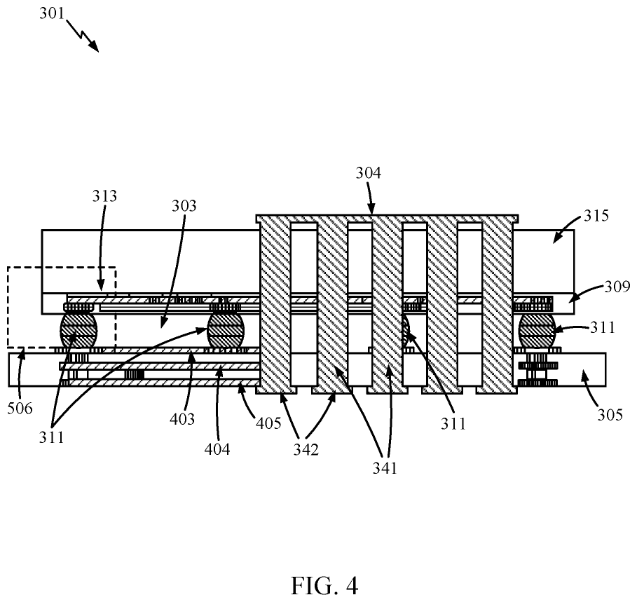

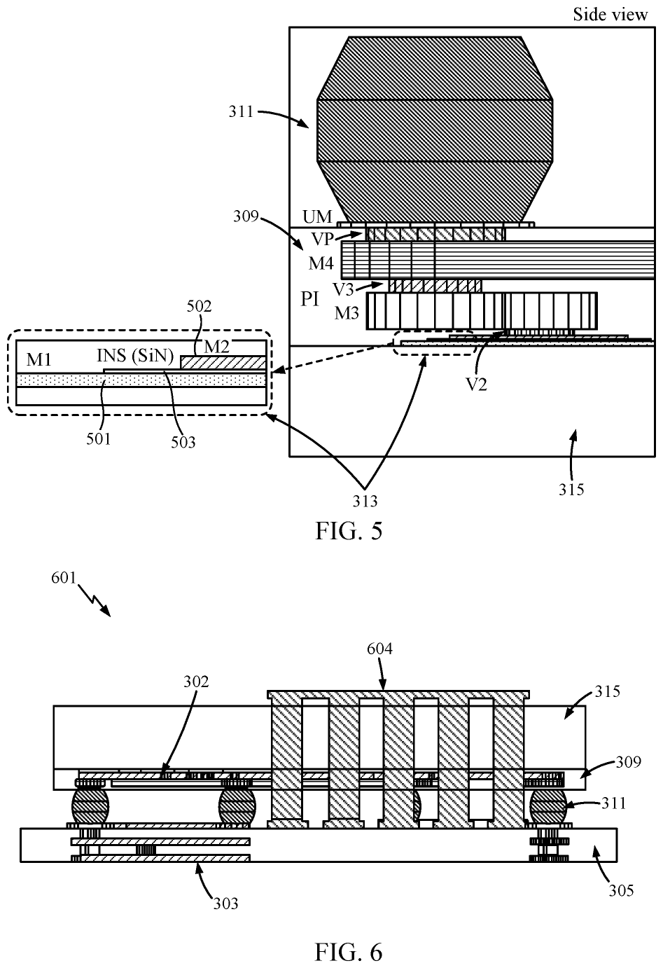

FIG. 4 is a graphical illustration of an alternate view of the filter 301 illustrated in FIG. 3. FIG. 4 shows a side view of filter 301, to further make clear details of its configuration. In FIG. 4, RDL in substrate 305 contains the layers, 403, 404, 405 used to form the coils of 2.5D inductor 303. A top metal layer 403 may be used to form one of the coils to allow for connection without using any internal conductive vias. A solder ball 311 or other conductive coupling element is used to couple the top metal layer 403 to die 309, which allows for electrical coupling to the 2D inductor 302 and MIM capacitors 313, which may be formed in die 309. Additional solder balls 311 or other conductive coupling elements can be used to couple other elements from RDL in substrate 305 to die 309, such as the 3D inductor 304 and other ends of the 2.5D inductor 303. Additionally, as shown in FIG. 4, die 309 may be mounted on a glass substrate 315. In this configuration, the 3D inductor 304 may wrap around both the RDL in substrate 305, die 309 and glass substrate 315. Further, in the 2D illustration of the 3D inductor 304, the conductive connections 342 are illustrated as being connected on the top, since the top conductive connections 342, as illustrated in FIG. 3, are diagonally connected to an opposite side conductive pillar 341. Likewise, the bottom connections 342 are illustrated as separate, since the bottom conductive connections 342, as illustrated in FIG. 3, are connected to an opposite side conductive pillar 341 that is generally directly opposite. It will be appreciate that the various 2D /flat representations included herein are provide to aid in the illustration of various elements and provide simple references, so the illustrations, should be considered in the context of the other aspects disclosed herein and not literally interpreted regarding size, placements, etc. Finally, a portion 506 represents a detail section that will be discussed further in relation to FIG. 5.

FIG. 5 is a magnified illustration of a portion 506 of the filter illustrated in FIGS. 3 and 4. In FIG. 5 a detailed view of a MIM capacitor 313 is also illustrated. The MIM capacitor 313 is formed in die 309 and comprises a first metal layer (M1) 501, an insulating layer 503 and a second metal layer (M2) 502. A plurality of MIM capacitors 313 may be formed in die 309. The insulating layer 503 may be silicon nitride (SiN) compound or any other suitable insulating material. Additional metal layers (e.g., M3, M4 and UM) may be used for interconnections between the various layers using vias (e.g., V2, V3, and VP) to connect to the MIM capacitor 313, external (e.g., via solder balls 311, solder bumps, or other electrical connector) and/or internal components of die 309, such as other capacitors or inductors (e.g., 2D inductor 302, which may be formed using part of metal layer M4 of die 309, for example).

FIG. 6 is a graphical illustration of another filter 601 (illustrated as a triplexer) including 2D, 2.5D and 3D inductive portions as well as capacitive portions, according to an aspect disclosed herein. 2D (2 dimensional) inductors are shown generally at 302. A 2.5D inductor 303 may be formed using two or more layers of a redistribution layer (RDL) in substrate 305. However, in this illustrative aspect, the bottom conductive connections do not extend through the RDL in substrate 305, but instead may be formed in a top metal layer of the RDL or a metal layer on the substrate 305. Other elements of the filter 601 similar to those described in the foregoing disclosure in relationship to FIGS. 3-5 will not be repeated here for brevity.

It will be appreciated that the foregoing variations are among many variations contemplated to be within the scope of the present disclosure. For example, which layer and how many metal layers used for the various components may be subject to various design choices, materials used, desired inductance, capacitance and/or frequency responses desired.

For example, one aspect can include a filter comprising a die (e.g., 309) having a plurality of Metal Insulator Metal (MIM) capacitors (e.g., 313) disposed within the die. The filter also includes a 2.5D (2.5 Dimensional) inductor (303) disposed within a redistribution layer (RDL) and electrically coupled to at least one of the plurality of MIM capacitors. The filter further includes a 3D (3 Dimensional) inductor (e.g., 304), wherein the 3D inductor is disposed around the die (e.g., 309) and is electrically coupled to at least one of the plurality of MIM capacitors. It will be appreciate that this filter arrangement allows for a compact filter, while still maintain high Q values for the inductors. In a further aspect, a 2D (2 Dimensional) inductor (e.g., 302) can be disposed within the die (e.g., 309) and electrically coupled to at least one of the plurality of MIM capacitors (e.g., 313). The 3D inductor can be formed in part by conductive pillars being disposed within or on the RDL in a substrate (e.g., 305). In one aspect, the conductive pillars may extend to a metal layer at or near a side of the RDL opposite a side facing the die (e.g., 309). Alternatively, the conductive pillars may extend to a metal layer at or near a surface of the RDL in the substrate (e.g., 305) facing the die (e.g., 309). These various aspects allow for a filter with multiple frequency bands and configured in various physical arrangements, while maintain a compact form factor and high Q values. Accordingly, the foregoing illustrations are merely provided as examples for discussion of the disclosed aspects.

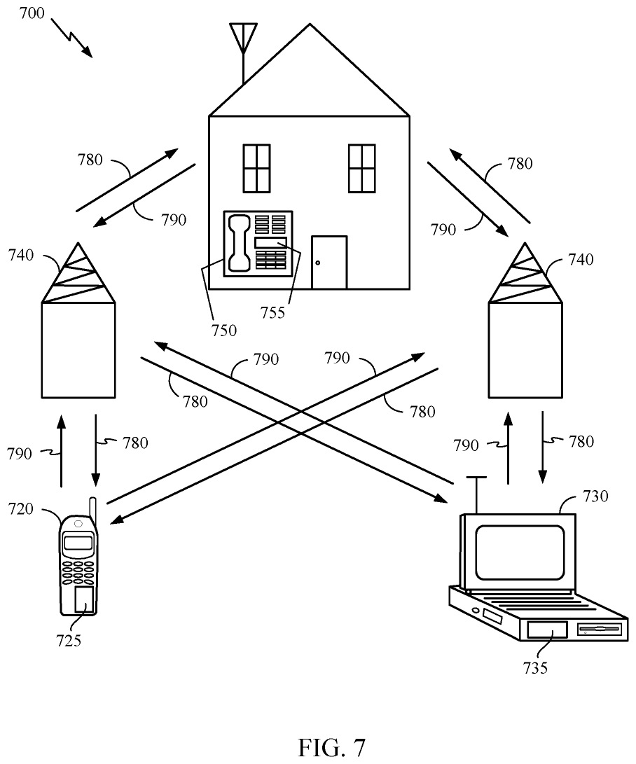

FIG. 7 illustrates an exemplary communication system 700 in which devices may include one or more aspects of the disclosure, e.g., as described in reference to any one or more of FIGS. 2-6. For purposes of illustration, FIG. 7 shows three remote units 720, 730, and 750 and two base stations 740. It will be recognized that conventional wireless communication systems may have many more remote units and base stations. The remote units 720, 730, and 750 include integrated circuit or other semiconductor devices 725, 735 and 755, respectively, having one or more filters in accordance with one or more of the disclosed exemplary aspects as claimed or as described in reference to any one or more of FIGS. 2-6. FIG. 7 shows forward link signals 780 from the base stations 740 and the remote units 720, 730, and 750 and reverse link signals 790 from the remote units 720, 730, and 750 to the base stations 740.

In FIG. 7, the remote unit 720 is shown as a mobile telephone, the remote unit 730 is shown as a portable computer, and the remote unit 750 is shown as a fixed location remote unit in a wireless local loop system. These are only examples, both in terms of quantity and type. For example, the remote units 720, 730 and 750 may be one of, or any combination of a mobile phone, hand-held personal communication system (PCS) unit, portable data unit such as a personal data assistant (PDA), navigation device (such as GPS enabled devices), set top box, music player, video player, entertainment unit, fixed location data unit such as meter reading equipment, or any other device that receives or transmits wireless signals or any combination thereof. Although FIG. 7 illustrates remote units 720, 730 and 750 according to aspects of the disclosure, the disclosure is not limited to these exemplary illustrated units. Aspects of the disclosure may be suitably employed in any device receiving or transmitting on multiple frequencies. For example, those skilled in the art will appreciate that aspects of the present disclosure may be incorporated into integrated devices, such as a mobile phone, which incorporate RF (Radio Frequency) communications in order to separate different frequency RF signal bands.

For example, the filter (e.g., 301) disclosed herein may be incorporated into a device that may include a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, or a device in an automotive vehicle. Further, it will be appreciated that aspects of the present disclosure may be used a wide variety of devices and are not limited to the specific examples provide herein.

The foregoing disclosed devices and functionalities, e.g., as described in reference to any one or more of FIGS. 2-6 and FIGS. 8-17, may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into a semiconductor chip. The chips are then employed in devices described above.

In order to fully illustrate aspects of the design of the present disclosure, methods of fabrication are presented. Other methods of fabrication are possible, and the method of fabrication is presented only to aid understanding of the concepts disclosed herein.

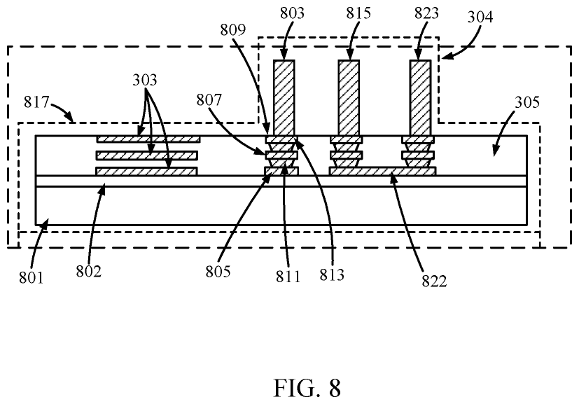

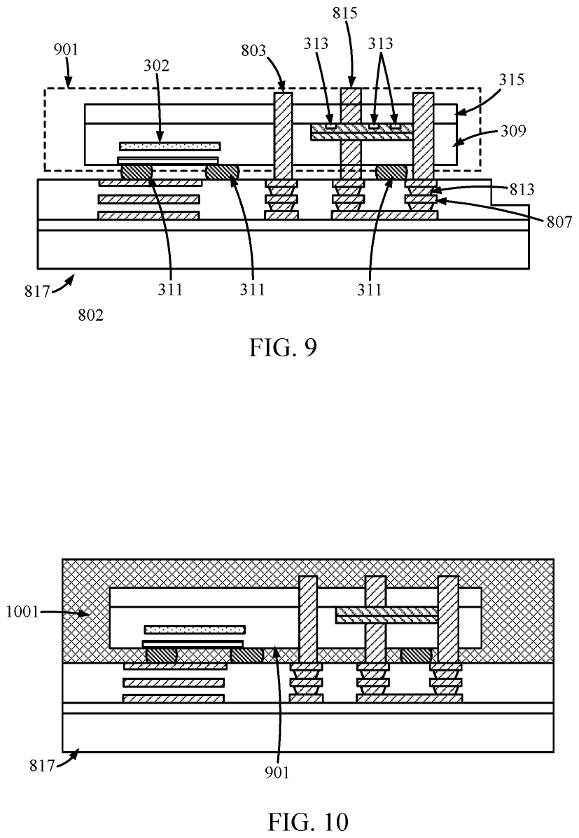

FIG. 8 is a graphical illustration of part of a process that may be used to form filters according to aspects of the disclosure. In FIG. 8, a carrier 801, also known as a carrier wafer, carrier strip or a carrier panel, supports a temporary polymer layer 802, which may be removed, in whole or in part using chemical, mechanical or thermal means. Three layers of metallization of substrate 305 form the 2.5D inductor 303. Part of the 3D inductor (e.g., 3D inductor 304 of FIG. 3) may also be formed using the RDL of substrate 305. Successive metal layers can be coupled vertically using conductive vias to form a portion of the 3D inductor 304. For example, three metal pads 805, 807 and 809 within the RDL in substrate 305 are connected to the pillar 803 through via connections 811 and 813. It will be appreciated that this pad and via coupling can be extended through more or less layers as desired and the configuration illustrated is merely an example to aid in the explanation of the various aspects. Pillar 815 can be electrically coupled to pillar 823 using any of the metallization layers coupled to pads or can be coupled externally. For example, conductive connection 822 can be formed on a bottom metallization layer and used to couple pillars 815 and 823 to form part of the windings of the 3D inductor. The drawings presented are flattened to 2D representations for simplicity. It will be appreciated that the pillars (e.g., 803, 815, and 823) may be staggered on opposite sides of the substrate 305 and the conductor 822 may cross the RDL to form part of the 3D inductor. Further, it will be appreciated that the choice of which metal layer to use to electrically couple pillars 823 and 815 can be determined by the inductance desired, interference with other components or connections, and other design choices. Additional pillars can be formed and coupled in a similar manner to form the 3D inductor. The assembly 817 may then be attached to assembly 901, as illustrated in FIG. 9.

FIG. 9 is a graphical illustration of part of the process that may be used to form filters according to aspects of the disclosure. In FIG. 9, assembly 901 is attached to assembly 817. The attachment may be accomplished with solder balls 311. Such attachments may be of any type suitable in the art, but for the purposes of illustration solder balls 311 or bumps are illustrated. Additionally, assembly 901 may be attached to assembly 817 using a flip chip process, as is known in the art. Assembly 901 includes a die 309 mounted on a glass substrate 315, the die 309 illustratively containing a 2D inductor 302 and a plurality of MIM capacitors 313. The assembly 901 may fit within pillars 803 and 815 and corresponding pillars (not illustrated) on the other side. Alternatively, holes may be drilled in the assembly 901 to accommodate pillars 803 and 815, if necessary.

FIG. 10 is a graphical illustration of part of the process that may be used to form filters according to aspects of the disclosure. FIG. 10 illustrates an over molding 1001 formed at least partially around the complete assembly 901 and on top of assembly 817.

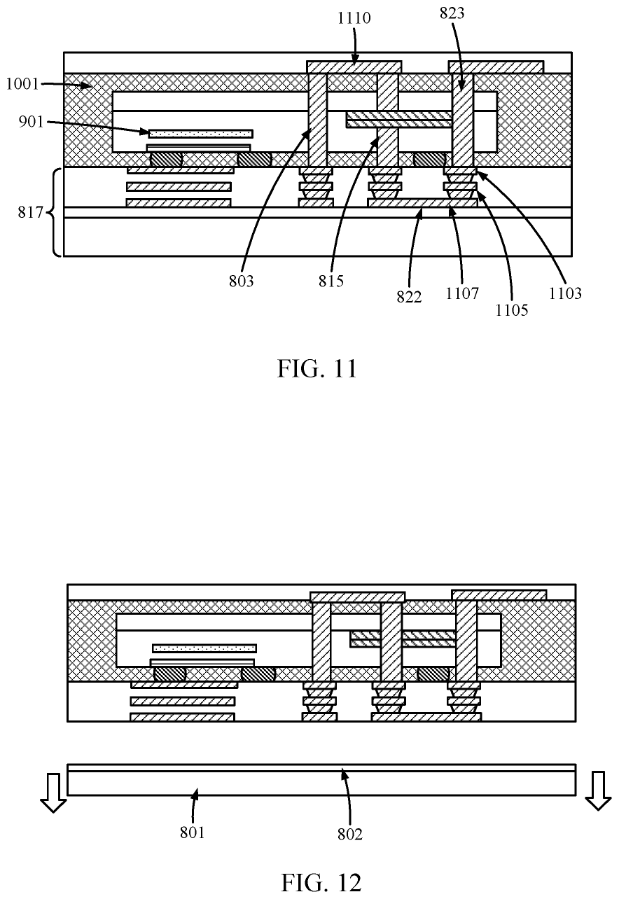

FIG. 11 is a graphical illustration of part of the process that may be used to form filters according to aspects of the disclosure. In FIG. 11, the over molding 1001 is ground down to expose the top of the conductive pillars (e.g., 803, 815 and 823). Once the grinding has exposed conductive pillars (e.g., 803, 815 and 823) they may be coupled through conductor 1101 using standard metallization techniques. Additionally, as illustrated by conductor 822, the bottom portions of pillars 823 and 815 to form the bottom part of the inductor winding. Conductor 822 may be formed in one or more metal layers in the RDL, as discussed in relation to FIG. 8 or may be formed later as an external conductor to the RDL. Regardless of the formation technique, by coupling the conductive pillars (e.g., 803, 815, and 823) on the top and bottom a 3D inductor can be formed. The drawings presented are flattened to 2D representations for simplicity. It will be appreciated that the pillars (e.g., 803, 815, and 823) may be alternately staggered on opposite sides and the conductors 1101 and 822 will cross the die and RDL to form the 3D inductor (e.g., 304, as illustrated in FIG. 3). Further, it will be appreciated that many various techniques may be used to form and couple the pillars, so the examples provided herein are merely provided for to serve as an aid for explanation and should not be construed literally to limit the various aspects or the disclosure.

The 3D inductor may have different inductances depending on the number of windings, length of windings, etc. For example, connecting through one of various metal layers, using pads 1103, 1105, or 1107 could be used to tune the inductance, with the winding length using pad 1107 being longer than the winding length if pad 1103 is used to connect the conductive pillars to form the 3D inductors. There may be many more than three metal layers in the RDL part of assembly 817 and the illustrations are provided solely as examples for explanation of the various aspects.

FIG. 12 is a graphical illustration of part of the process that may be used to form filters according to aspects of the disclosure. In FIG. 12, the carrier 801, and optionally the temporary polymer layer 802 may also be released.

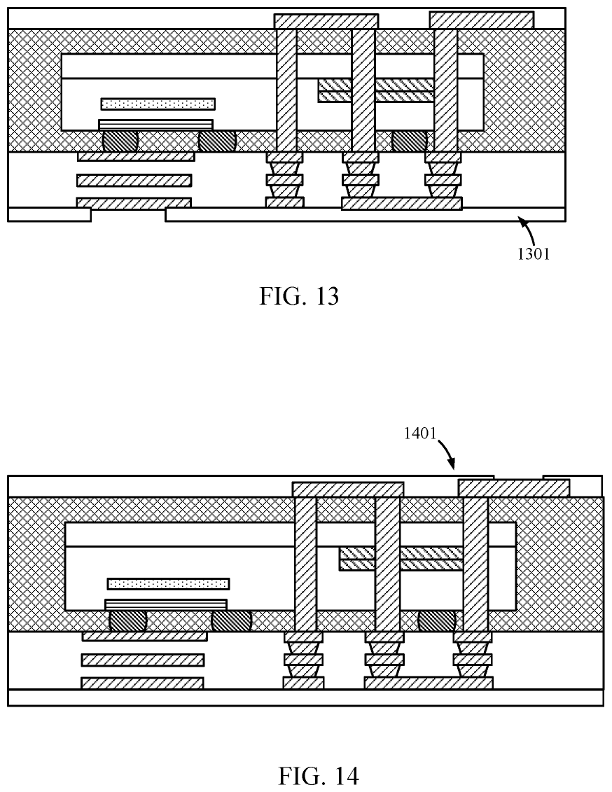

FIG. 13 is a graphical illustration of an optional part of the process that may be used to form filters according to aspects of the disclosure. In FIG. 13, a passivation layer 1301 may be added along with solder balls to the completed filter assembly. Alternatively, other connection technologies besides solder balls can be used to form electrical attachments to the desired circuitry and/or the passivation layer 1301 could be eliminated.

FIG. 14 is a graphical illustration of an optional part of the process that may be used to form filters according to aspects of the disclosure. In FIG. 14, a passivation layer 1401 may include an opening on a side opposite of the of 2.5D inductor portion to minimize inductance change due to customers' printed circuit boards (PCBs) ground plane variations or other magnetic or electrical couplings.

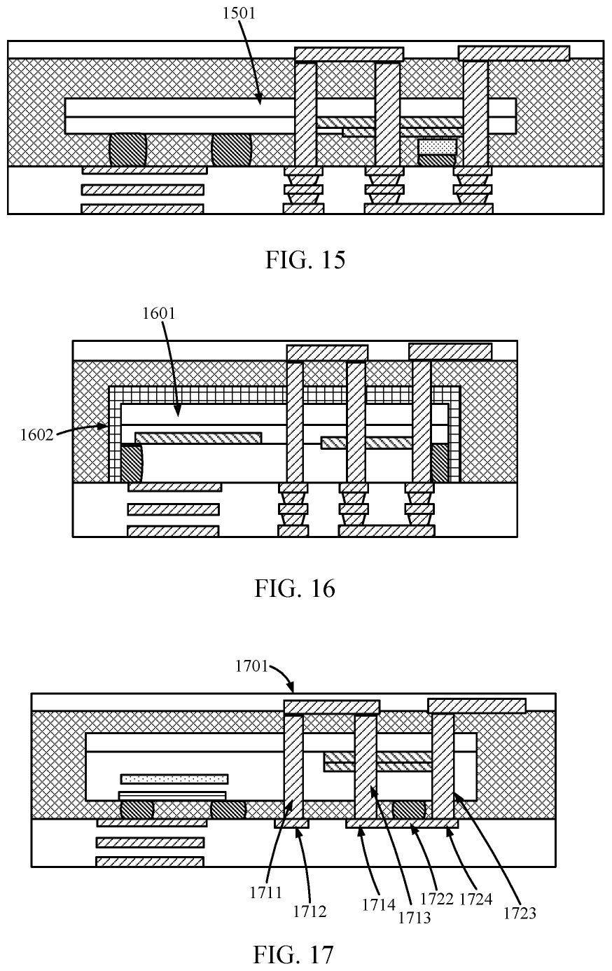

FIG. 15 is a graphical illustration depicting an alternate embodiment of the aspects disclosed herein. In FIG. 15, die 1501 may be fabricated containing BAW (Bulk Acoustic Wave) filters instead of, or in addition to, other components such as MIM (Metal Insulator Metal) capacitors. However, in this configuration, the 2D inductor is not included in die 1501. The details of fabricating die configurations containing BAW filters are known to those skilled in the art, so a detailed description will not be provided herein.

FIG. 16 is a graphical illustration depicting an alternate aspect of the disclosure. In FIG. 16, die 1601 may be fabricated containing on or more Surface Acoustic Wave (SAW) filters instead of, or in addition to, other components such as MIM capacitors. Additionally, an optional encapsulation layer 1602 may be formed over the die 1601. For example, the die 1601 may be encapsulated using Glob Top encapsulation or other encapsulation techniques. Additionally, in this configuration, the 2D inductor is not included in die 1601. The details of fabricating die configurations with SAW filters are known to those skilled in the art, so a detailed description will not be provided herein.

FIG. 17 is a graphical illustration depicting aspects of an alternate aspect of the disclosure. In FIG. 17, a 3D inductor 1701 includes conductive pillars 1711, 1713 and 1723 with pads 1712, 1714 and 1724 on the top layer of the RDL without the stacked pad and via configuration (e.g., as shown in some of the prior illustrations). It will be appreciated that pads 1714 and 1724 can be connected by conductive connection 1722 to form part of the 3D inductor. Alternatively, conductive connection 1722 may be formed in direct contact with conductive pillars 1713 and 1723, if the pad configuration is not used. It will be appreciated that regardless of the forming and coupling, the conductive pillars and conductive connections form the 3D inductor. In one example, this configuration can be used to improve the inductor Q factor (i.e., trading off with inductance density). The details of fabricating this alternative configuration is supported by the foregoing disclosure and additional techniques which are known to those skilled in the art, so a detailed description will not be provided herein.

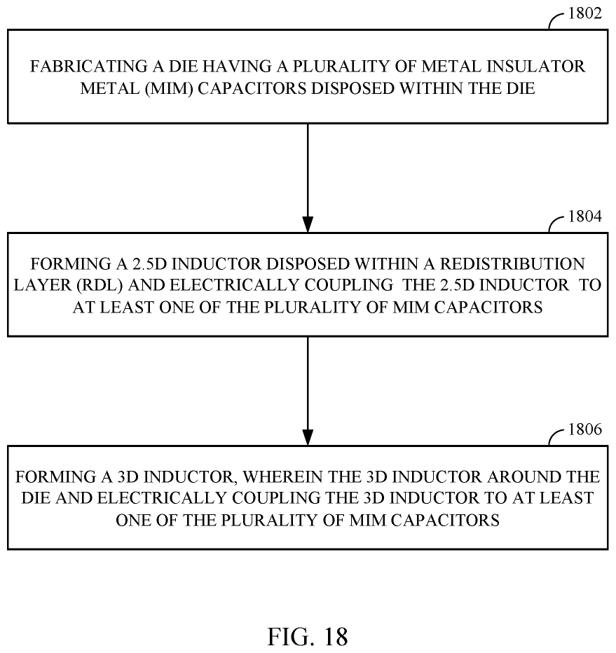

It will be appreciated from the foregoing that there are various methods for fabricating filters according to aspects disclosed herein. FIG. 18 is a flowchart of a method for fabricating a filter in accordance with at least one aspect disclosed. For example, block 1802 includes fabricating a die having a plurality of Metal Insulator Metal (MIM) capacitors disposed within the die. Block 1804 includes forming a 2.5D inductor disposed within a redistribution layer (RDL). The 2.5D inductor is electrically coupled to at least one of the plurality of MIM capacitors. Block 1806 includes forming a 3D inductor around the die and is electrically coupled to at least one of the plurality of MIM capacitors. It will be appreciated from the foregoing disclosure that additional processes for fabricating the various aspects disclosed herein will be apparent to those skilled in the art and a literal rendition of the processes discussed above and illustrated in the included drawings will not be provided.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, embodiments disclosed herein can include a non-transitory computer-readable media embodying a method for fabricating the various filters. Accordingly, the disclosure is not limited to illustrated examples as any means for performing the functionality described herein are contemplated by the present disclosure.

While the foregoing disclosure shows various illustrative embodiments, it should be noted that various changes and modifications could be made herein without departing from the scope of the teachings of the present disclosure as defined by the appended claims. The functions, steps and/or actions of the method claims in accordance with the embodiments of the disclosure described herein need not be performed in any particular order. Furthermore, although elements of the present disclosure may be described or claimed in the singular, the plural is contemplated unless limitation to the singular is explicitly stated.

What is claimed is:

1. A filter comprising:
a die having a plurality of Metal Insulator Metal (MIM) capacitors disposed within the die;
a 2.5D (2.5 Dimensional) inductor disposed within a redistribution layer (RDL) and electrically coupled to at least one of the plurality of MIM capacitors; and
a 3D (3 Dimensional) inductor, wherein the 3D inductor is disposed around the die and is electrically coupled to at least one of the plurality of MIM capacitors.

2. The filter of claim 1, further comprising:
a 2D (2 Dimensional) inductor disposed within the die and electrically coupled to at least one of the plurality of MIM capacitors.

3. The filter of claim 1, wherein the 3D inductor is formed in part by conductive pillars substantially perpendicular to a surface of the die, each conductive pillar coupled to at least one other conductive pillar via conductive connections substantially parallel to the surface of the die.

4. The filter of claim 3, wherein the conductive pillars are copper pillars.

5. The filter of claim 3, wherein the 3D inductor is further formed in part by the conductive pillars being disposed within the RDL in a substrate, where the conductive pillars extend to a metal layer at or near a side of the RDL of the substrate, opposite a side facing the die.

6. The filter of claim 5, wherein the conductive pillars extend through the RDL as a series of metal pads and vias through various layers of the RDL.

7. The filter of claim 3, wherein the 3D inductor is further formed in part by the conductive pillars being disposed on a metal layer of the RDL in a substrate at or near a surface facing the die and at least one conductive pillar being coupled to at least one other conductive pillar by a conductive connection on the metal layer at or near the surface facing the die.

8. The filter of claim 1, wherein the 2.5D inductor is formed from a plurality of conductive coils each disposed on a separate layer of the RDL and each being coupled to at least one other of the plurality of conductive coils.

9. The filter of claim 1, wherein the die further includes a bulk acoustic wave (BAW) filter or a surface acoustic wave acoustic (SAW) filter.

10. The filter of claim 8, further comprising:
an encapsulation layer that at least partially surrounds the die.

11. The filter of claim 1, wherein the die is coupled to the RDL in a flip chip configuration.

12. The filter of claim 1, wherein the die is a glass die.

13. The filter of claim 1, wherein the die is a high-resistivity silicon die.

14. The filter of claim 1, further comprising:
a glass substrate, wherein the die is mounted to the glass substrate and the glass substrate is on an opposite side of the die from the RDL.

15. The filter of claim 14, further comprising:
a passivation layer on the RDL with at least one opening to allow connections to external circuitry.

16. The filter of claim 14, further comprising:
a molding compound, wherein the die and the glass substrate is embedded in the molding compound.

17. The filter of claim 16, further comprising:
a passivation layer on the molding compound with at least one opening to allow connections to external circuitry to the 3D inductor.

18. The filter of claim 17, further comprising:
a passivation layer on the RDL with no openings adjacent the 2.5D inductor.

19. The filter of claim 1, further comprising:
a molding compound, wherein the die is embedded in the molding compound and at least a portion of the 3D inductor extends beyond the molding compound.

20. The filter of claim 1, further comprising:
an encapsulation layer that at least partially surrounds the die, wherein the encapsulation layer is between the die and a molding compound.

21. The filter of claim 1, wherein the filter is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a component in an automotive vehicle.

22. A method for fabricating a filter comprising:
fabricating a die having a plurality of Metal Insulator Metal (MIM) capacitors disposed within the die;
forming a 2.5D (2.5 Dimensional) inductor disposed within a redistribution layer (RDL), and electrically coupling the 2.5D inductor to at least one of the plurality of MIM capacitors; and
forming a 3D (3 Dimensional) inductor around the die and electrically coupling the 3D inductor to at least one of the plurality of MIM capacitors.

23. The method of claim 22, further comprising:
forming a 2D (2 Dimensional) inductor disposed within the die; and
electrically coupling the 2D inductor to at least one of the plurality of MIM capacitors.

24. The method of claim 22, wherein the 3D inductor is formed in part by conductive pillars coupled via conductive connections substantially parallel to a surface of the die.

25. The method of claim 24, wherein the 3D inductor is further formed in part by the conductive pillars that are disposed within the RDL where the conductive pillars extend to a metal layer at or near an opposite side of the RDL surface facing the die.

26. The method of claim 24, wherein the 3D inductor is further formed in part by the conductive pillars disposed on metal layer of the RDL at or near a surface facing the die.

27. The method of claim 22, further comprising:
at least partially encapsulating the die with an encapsulation layer.

28. The method of claim 22, further comprising:
coupling the die to the RDL in a flip chip configuration.

29. The method of claim 22, further comprising:
forming a passivation layer on the RDL; and
forming at least one opening in the passivation layer to allow connections to external circuitry.

30. The method of claim 22, further comprising:
mounting the die to a glass substrate, wherein to the glass substrate is on an opposite side of the die from the RDL.
